(19) United States
(12) Patent Application Publication
(10) Pub. No.: US 2016/0209486 A1
(43) Pub. Date: Jul. 21, 2016

(54) MOTION SENSOR

(71) Applicant: Siemens Aktiengesellschaft, Muenchen (DE)

(72) Inventors: Martin Nisznansky, Moehrendorf (DE); Robert Rehner, Neunkirchen am Brand (DE); Markus Vester, Nuernberg (DE)

(73) Assignee: Siemens Aktiengesellschaft, Muenchen (DE)

(21) Appl. No.: 14/995,408

(22) Filed: Jan. 14, 2016

(30) Foreign Application Priority Data
Jan. 15, 2015 (DE) 102015200510.0

(51) Int. Cl. G01R 33/567; G01R 33/565

(52) U.S. Cl. CPC G01R 33/5673; G01R 33/56509

(57) ABSTRACT

A motion sensor for detecting movements of a patient in an imaging medical system, in particular in a magnetic resonance tomography system has at least one HF resonator for emitting an HF signal fed into the resonator from an HF signal source and for receiving a response signal, and a detection circuit for detecting movements of the patient derived from the received signal.

### BACKGROUND OF THE INVENTION

1. Field of the Invention

The invention concerns motion sensors and methods for detecting movements of a patient in a medical imaging system, in particular a magnetic resonance tomography system.

2. Description of the Prior Art

Examples of methods for detecting movements (in particular for respiratory detection) in a magnetic resonance tomography system are described in the following documents.

The publication Buikman, Helzel, Roschmann: The Coil as a Sensitive Motion Detector for MRI-Magnetic-Resonance-Imaging, Vol. 6, Num. 3, 1988 belonging to Philips describes that the respiratory movement can be detected by measuring the reflection factor of the body coil of an MRT.

DE 10 2014 209 488.7 by R. Rehner, A. Fackelmeier and S. Biber relates to “Respiratory detection by posterior high-frequency coils close to the body”, with the respiratory detection being described by a measurement of the reflection factor of a sensor coil under the patient.

DE 19 2009 052 412 A1 relates to a “Measuring system for detecting the position of a moving organ”.

### SUMMARY OF THE INVENTION

An object of the present invention is to optimize a medical device (in particular magnetic resonance tomography system) with respect to movement detection.

In accordance with the invention, a motion sensor for detecting movements of a patient in an imaging medical system, in particular in a magnetic resonance tomography system has at least one HF resonator for emitting an HF signal fed into the resonator from an HF signal source and for receiving a response signal, and a detection circuit for detecting movements of the patient derived from the received signal.

### BRIEF DESCRIPTION OF THE DRAWINGS

FIG. 1 shows an exemplary embodiment of a scanning arrangement with an open LC resonator.

FIG. 2 shows scanned changes in the transmission S21 due to a body movement.

FIG. 3 shows scanned temporal changes in the transmission S21 due to breathing.

FIG. 4 schematically shows an MRT system.

### DESCRIPTION OF THE PREFERRED EMBODIMENTS

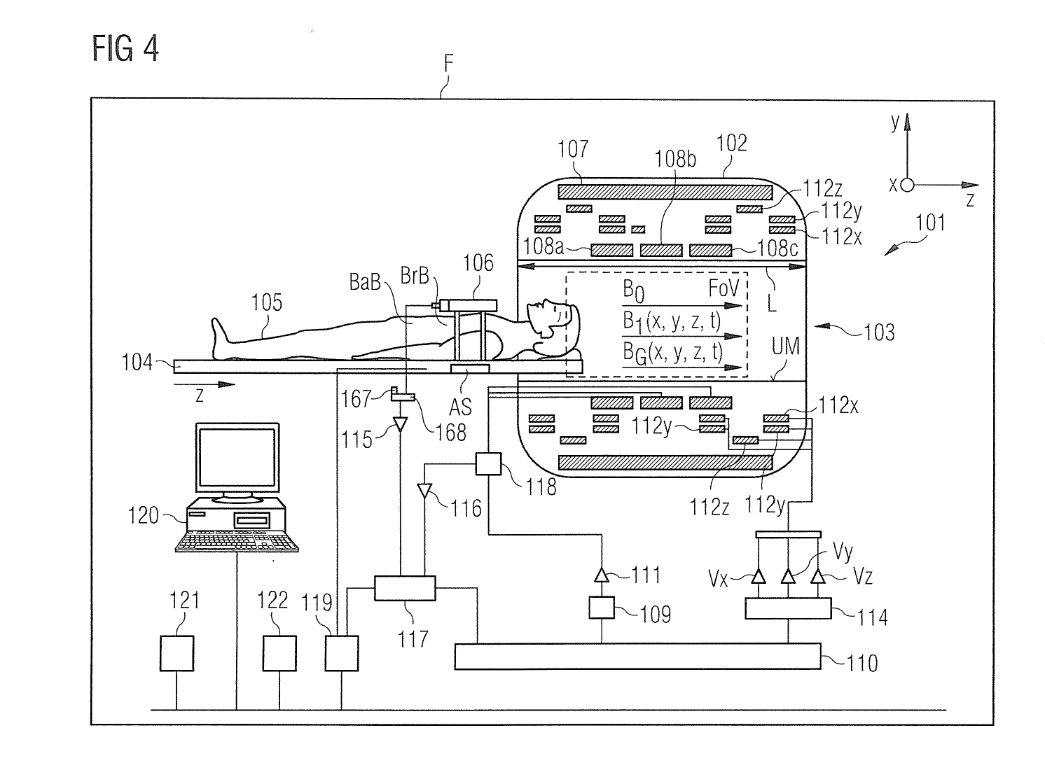

FIG. 4 shows (in particular in relation to the technical background as well) an imaging magnetic resonance scanner 101 (located in a shielded space or Faraday cage F) having a hollow cylinder 102 with a tubular space 103 in which an examination table 104 with a body 105, for example of an examination object (such as a patient; with or without local coil arrangement 106) can be moved in the direction of the arrow z to generate scans of the patient 105 by execution of an imaging method. A local coil arrangement 106 is arranged on the patient 105 here, with which MRT scans of a section of the body 105 can be generated in the FoV (also called Field of View or FoV) in a local region. Signals of the local coil arrangement 106 can be evaluated by an evaluation device (168, 115, 117, 119, 120, 121 etc.) of the magnetic resonance scanner 101 that can be connected for example by coaxial cables or via radio (167), etc. to the local coil arrangement 106 (for example in converted into images, stored or displayed).

To examine a body 105 (an examination object or a patient) by magnetic resonance imaging using a magnetic resonance device magnetic resonance scanner 101, different magnetic fields that are matched as accurately as possible to each other in terms of their temporal and spatial characteristics are irradiated onto the body 105. A strong magnet (often a cryomagnet 107) in a measuring booth having a tunnel-like opening 103 here generates a static strong main magnetic field B₀, which amounts to, for example, 0.2 tesla to 3 tesla or more. A body 105 to be examined, positioned on an examination table 104, is moved into a region of the main magnetic field B0 that is substantially homogeneous in the field of observation FoV (also called “Field Of View” or “field of view”). The nuclear spins of atomic nuclei of the body 105 are excited by magnetic high-frequency excitation pulses B1(x, y, z, t) which are irradiated by a high-frequency antenna (and/or optionally a local coil arrangement) shown in very simplified form here as a (for example multi-part=108a, 108b, 108c) body coil 108. High-frequency excitation pulses are generated for example by a pulse-generating unit 109 which is controlled by a pulse sequence control unit 110. After amplification by a high-frequency amplifier 111 they are led to the high-frequency antenna 108. The high-frequency system shown here is only indicated schematically. More than one pulse-generating unit 109, more than one high-frequency amplifier 111 and a plurality of high-frequency antennae 108 a, b, c are potentially also used in one magnetic resonance device 101.

The magnetic resonance scanner 101 also has gradient coils 112x, 112 y, 112 z with which magnetic gradient fields B_{G}(x, y, z, t) can be irradiated during a scan for selective slice excitation and for spatial encoding of the scan signal. The gradient coils 112x, 112y, 112z are controlled by a gradient coil control unit 114 (and optionally by amplifiers Vx, Vy, Vz) which, like the pulse-generating unit 109, is also connected to the pulse sequence control unit 110.

Signals emitted by the excited nuclear spins (of the atomic nuclei in the examination object) are received by the body coil 108 and/or at least one local coil arrangement 106, amplified by associated high-frequency pre-amplifier 116 and processed further by a receiving unit 117 and digitized. The recorded scan data is digitized and stored as complex numerical values in a k-space matrix. An associated MR image can be reconstructed from the k-space matrix with assigned values by means of a multi-dimensional Fourier transformation.

For a coil which can be operated in both transmitting and receiving modes, such as e.g. the body coil 108 or a local coil 106, the correct signal forwarding is regulated by an upstream duplexer 118.

From the scan data an image processing unit 119 generates an image which is displayed for a user and/or stored in a memory unit 121 via a control console 120. A central arithmetic unit 122 controls the individual system components.

In MR tomography images with a high signal-to-noise ratio (SNR) are currently usually recorded using what are known as local coil arrangements (coils, local coils). These are antenna systems which are provided in the immediate vicinity on top of (anterior) or below (posterior) or on or in the body 105. During an MR scan the excited nuclei induce a voltage in the individual antennae of the local coil and this is then amplified using a low-noise pre-amplifier (for example LNA, Preamp) and is finally forwarded to the electronic receiving device. What are known as high field systems (1.5 T-12 T or more) are used to improve the signal-to-noise ratio even in high-resolution images. If more individual antennae can be connected to an MR receiving system than there are receivers, a switch matrix for example (sometimes also called an RCCS) is installed between receiving antennae and receivers. This routes the instantaneously active receiving channels (usually those which are located precisely in the field of view of the magnet) to the existing receivers. As a result it is possible to connect more coil elements than there are receivers since in the case of whole-body coverage only the coils which are located in the FoV or in the homogeneity volume of the magnet have to be read.

Generally an MR antenna system, which can be formed by one antenna element or, as an array coil, of multiple antenna elements (in particular coil elements), is designated a local coil arrangement 106. These individual antenna elements are designed, for example, as loop antennae (loops), butterfly, flex coils or saddle coils. A local coil arrangement includes for example coil elements, a pre-amplifier, further electronic devices (sheath wave traps, etc.), a housing, supports and usually a cable with connectors by which it is connected to the MRT system. A receiver 168, provided on the system, filters and digitizes a signal received by a local coil 106, for example via radio, etc., and passes the data to a digital signal processor which usually derives an image or a spectrum from the data obtained by a scan and makes it available to the user for example for subsequent diagnosis by him, and/or storage.

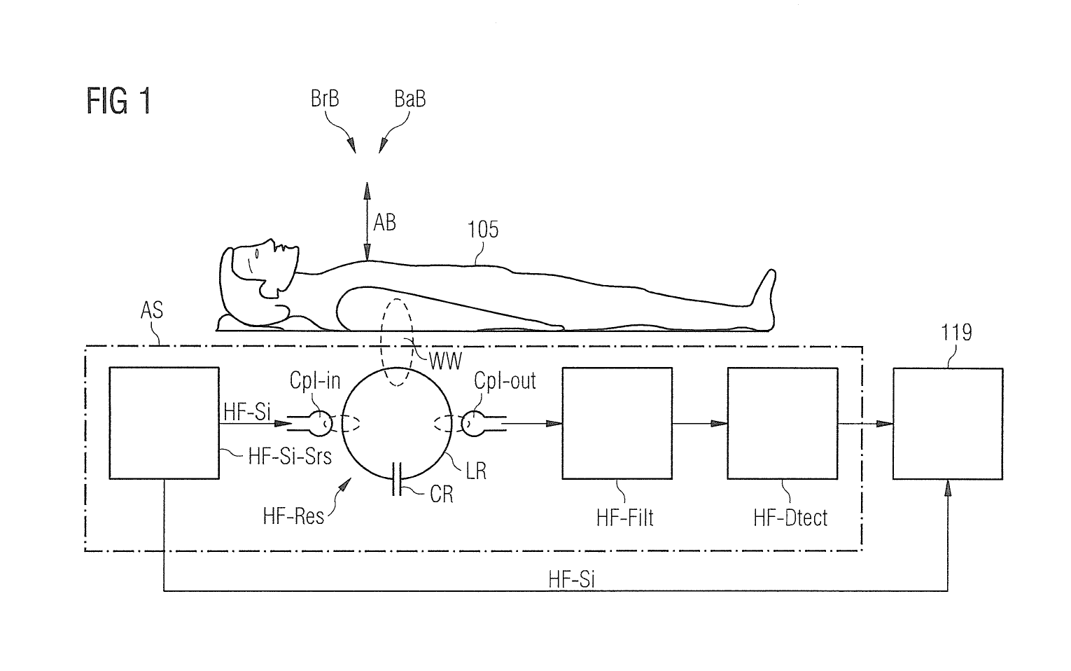

FIG. 1-4 shows some details of exemplary embodiments of the invention.

Undesirable patient movement during image recording can cause pronounced image artifacts in the case of medical imaging. Undesirable movement artifacts of this kind in the chest or abdominal region can be also be caused by breathing. For this reason it may be expedient to detect the patient breathing and to synchronize the (MRT) image recording with the respiratory cycle. This may be helpful in particular for magnetic resonance tomography (MRT) because the image recording (MR sequence) can last a few minutes and not every patient can hold their breath for that long.

FIG. 1 shows an embodiment of the invention with a placement of one more HF resonator(s) (resonant circuits) HF-Res in the vicinity of the patient 105 in the chest region BrB and/or abdominal region BaB. The HF resonator HF-Res (and/or motion sensor AS with electronic evaluation device) can be integrated, for example, in the examination table 104 of the magnetic resonance scanner 101. An HF signal from an HF generator (HF-Si-Srs) is coupled, for example, by a coupling coil Cpl-In (or capacitively by a coupling capacitor or by another type of coupling) into the HF resonator HF-Res. The HF signal generated in the HF generator HF-Si-Srs, and coupled into the HF resonator HF-Res is decoupled (by Cpl-out) from the HF resonator again (inductively or capacitively by, for example, a coupling capacitor or by another type of coupling) and is filtered and detected by the, for example narrowband, HF detector (HF-Filt and/or HF-Dtect).

Properties WW (such as here in particular quality) of the HF resonator are affected here by the breathing of the patient and consequently the transmission (S21) of the HF signal via the HF resonator also changes (i.e. the difference S21diff between S21-e in the case of a patient who has inhaled compared to S21-a in the case of a patient who has exhaled). This arrangement enables measurement of the transmission losses of the HF resonator HF-Res, as is shown in FIG. 1.

The HF resonator HF-Res is constructed here in such a way that the induced electromagnetic field HF-Si of the HF resonator HF-Res penetrates into the body of the patient 105 enabling an interaction WW between the HF resonator HF-Res and the body of the patient 105. A body movement AB (as well as for example a respiratory movement or a shift in the anatomy inside the body which also may not be outwardly visible) then causes a change in the loaded quality of the HF resonator HF-Res.

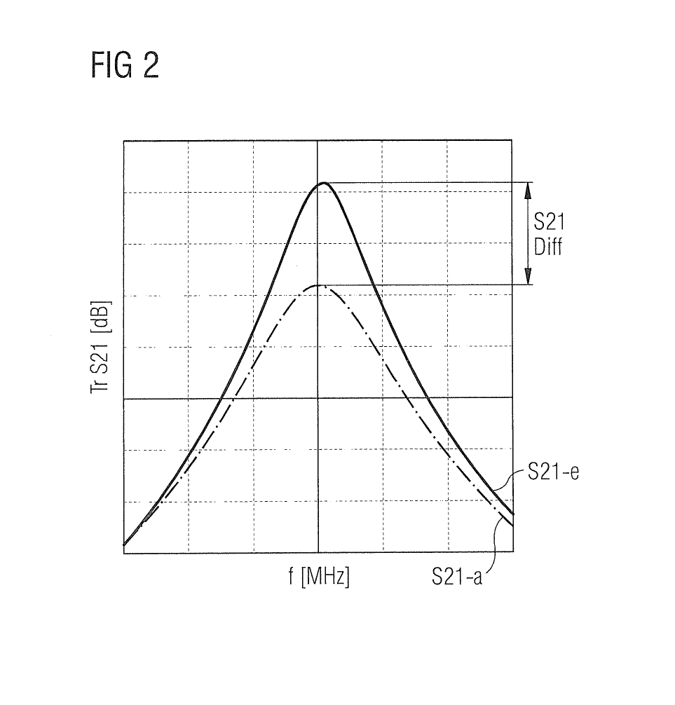

This can be detected, for example as shown in FIG. 2, as a change S21diff (as a difference in the transmission S-21-e when the body of the patient has inhaled and S21-a when the body has exhaled) in the transmission S21[dB] as a function of the frequency.

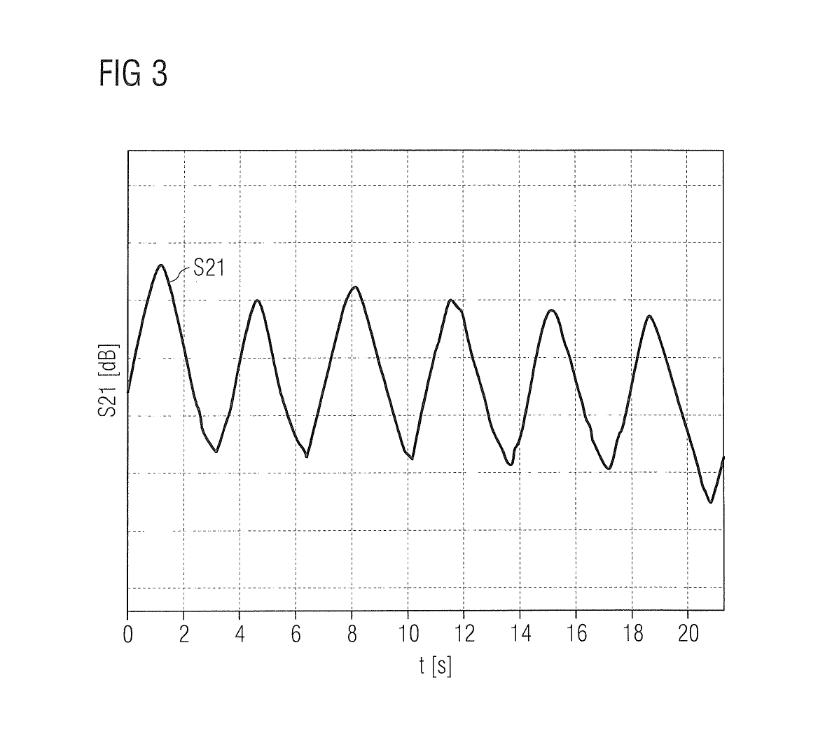

Respiratory movements AB of the patient 105 can also be measured as temporal changes S21-diff, shown in FIG. 3, in the transmission S21-e-S21-a (before and after inhaling) over the course of time t[s]. For an MRT application it is advantageous if the resonance frequency of the HF resonator HF-Res differs from the MR frequency of the magnetic resonance magnetic resonance scanner 101 so that little, or optimally no, mutual interference can occur between the motion sensor or respiratory sensor AS and MR imaging.

If the dimensions of the used HF resonator HF-Res are much smaller than the used wavelength of the scan signal, then the HF resonator HF-Res behaves, for example, like an inductive or capacitive sensor and not (or rarely) like an MRT imaging antenna (106), because work is carried out in the inductive (or capacitive) near field. The irradiated HF energy is consequently minimized.

Embodiments of the invention can be sensitive to respiration because the scanned transmission losses of an HF resonator HF-Res are dependent on the air-tissue distribution; the muscle-tissue can have large HF losses compared to the inhaled air.

A transmission scan does not require a directional coupler like a scan of the reflection factor, and can be less sensitive to mismatches in a scanning section.

Transmission scans according to the invention can be carried out in a large dynamic range and can be less ambiguous (zero crossing and change in sign) than a scan of the reflection factor.

An HF resonator HF-Res can work with negligible irradiation in a manner similar to an inductive sensor, insofar as only the near field is required for operation.

Contactless scanning can be enabled. The respiratory sensor does not have to be placed on the body of a patient 105 and secured.

Embodiments of the invention can have a negligible effect on the SAR balance (in contrast to MR navigators), insofar as the used HF signals can have a low power (of for example 1 mW).

A motion sensor AS can be integrated in an examination table 104. In this way the body spacing is always the same and, compared to other methods, no new, visible cabling is necessary. The spacing between a motion sensor AS and a patient 105 may be very constant in the case of a motion sensor AS integrated in an examination table 104, in particular compared to the alternative of placing the sensor above the patient behind the bore cladding.

Those skilled in the art know how a transmission scan could be carried out, for example, also from www.wikipedia.de. In principle S parameters, such as, for example, the forward transmission factor S21, are scanned with the use of network analyzers as a function of the frequency, see for example network analyzers illustrated in de.wikipedia.org/wiki/Netzwerkanalysator#mediaviewer/File:Vna3.png, although any other network analyzers may also be considered.

FIG. 1 shows an example of an HF Filter HF-Filt and an HF detector HF-Detect for detecting an HF signal.

Although modifications and changes may be suggested by those skilled in the art, it is the intention of the inventors to embody within the patent warranted hereon all changes and modifications as reasonably and properly come within the scope of their contribution to the art.

We claim as our invention:

1. A motion sensor for detecting movements of a subject in a medical imaging system, said motion sensor comprising:
at least one radio-frequency (RF) resonator;
an RF signal source in signal-feeding communication with said at least one RF resonator, said RF signal source generating an RF signal that is fed to said RF resonator and that causes said RF resonator to radiate an RF field in which said subject is situated; and
a detection circuit in signal-receiving communication with said RF resonator that detects signals produced by said RF resonator as a result of subject movement in said RF field, said detection circuit generating a detection circuit output signal that represents said movement.

2. A motion sensor as claimed in claim 1 wherein said medical imaging system is a magnetic resonance system in which RF excitation pulses, for obtaining magnetic resonance image data, are radiated at an excitation frequency, and wherein said signal source generates said RF signal that is fed to said RF resonator at a frequency that differs from said excitation frequency.

3. A motion sensor as claimed in claim 1 comprising a plurality of RF resonators.

4. A motion sensor as claimed in claim 1 wherein said RF resonator comprises an LC resonator comprising at least one coil and at least one capacitor.

5. A motion sensor as claimed in claim 1 wherein said detection circuit is a narrow band RF detection circuit.

6. A method as claimed in claim 1 wherein said detection circuit is configured to measure differences in the detected signal from the RF resonator that represent inhalation by the patient and exhalation by the subject, respectively.

7. A motion sensor as claimed in claim 1 wherein the subject is a patient, and wherein said RF resonator is configured for placement at a location relative to the patient selected from the group consisting of above a chest region of the patient, below a chest region of the patient, above an abdominal region of a patient and below an abdominal region of the patient.

8. A motion sensor as claimed in claim 1 wherein said medical imaging system comprises an examination table adapted to receive the subject thereon, and wherein at least said RF resonator is integrated in said examination table.

9. A motion sensor as claimed in claim 1 wherein said medical imaging system is a magnetic resonance imaging system comprising a scanner having a housing shell forming a patient receptacle adapted to receive the subject therein, and wherein said RF resonator is configured for placement above the patient in the receptacle, with the RF resonator being behind said housing shell.

10. A motion sensor as claimed in claim 1 wherein said RF resonator has resonator characteristic selected from the group consisting of a loaded quality and a transmission factor, and wherein said detection circuit is configured to detect said movement as a change in said resonator characteristic.

11. A motion sensor as claimed in claim 1 wherein said detection circuit is configured to detect said movement by evaluating a temporal change in transmission of said RF signal to said RF radiator.

12. A motion sensor as claimed in claim 1 wherein said RF signal has a wavelength, and wherein said RF resonator has physical dimensions that are smaller than said wavelength of said RF signal.

13. A motion sensor as claimed in claim 1 wherein said Rf resonator is configured as an inductive sensor operating in an inductive near field.

14. A motion sensor as claimed in claim 1 wherein said Rf resonator is configured as a capacitive sensor operating in a capacitive near field.

15. A motion sensor as claimed in claim 1 wherein said RF resonator is configured for placement relative to the subject without making contact with the subject.

16. A motion sensor as claimed in claim 1 wherein said RF source is configured to generate said RF signal with a power of less than 10 mW.

17. A motion sensor as claimed in claim 1 wherein said RF signal source and said detector circuit are capacitively coupled to said RF resonator.

18. A motion sensor as claimed in claim 1 wherein said RF signal source and said detector circuit are capacitively decoupled from said RF resonator.

19. A motion sensor as claimed in claim 1 wherein said RF signal source and said detector circuit are inductively coupled to said RF resonator.

20. A motion sensor as claimed in claim 1 wherein said RF signal source and said detector circuit are inductively decoupled from said RF resonator.

21. A medical imaging system comprising:
a motion sensor comprising at least one radio-frequency (RF) resonator, an RF signal source in signal-feeding communication with said at least one RF resonator, said RF signal source generating an RF signal that is fed to said RF resonator and that causes said RF resonator to radiate an RF field in which said subject is situated, and a detection circuit in signal-receiving communication with said RF resonator that detects signals produced by said RF resonator as a result of subject movement in said RF field, said detection circuit generating a detection circuit output signal that represents said movement;
a medical data acquisition scanner adapted to receive the subject therein;
a control computer configured to operate said medical data acquisition scanner to acquire medical data from the subject; and
said control computer being connected to said detector circuit and being configured to adapt the acquisition of said medical image data from the subject dependent on the motion represented in said detector circuit output.

22. A method for detecting motion of a subject in a medical imaging system, said method comprising
placing at least one radio-frequency (RF) resonator;
placing an RF signal source in signal-feeding communication with said at least one RF resonator and, in said RF signal source, generating an RF signal and feeding said RF signal to said RF resonator and to cause said RF resonator to radiate an RF field in which said subject is situated; and
placing a detection circuit in signal-receiving communication with said RF resonator and detecting signals produced by said RF resonator as a result of patient movement in said RF field and, from said detection circuit generating a detection circuit output signal that represents said movement.
